(19) United States
(12) Patent Application Publication
(10) Pub. No.: US 2010/0308893 A1
(43) Pub. Date: Dec. 9, 2010

(54) Semiconductor device and method of operating the same

(75) Inventor: Atsuhisa Fukuoka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/662,359

(22) Filed: Apr. 13, 2010

(30) Foreign Application Priority Data
Jun. 4, 2009 (JP) 134869/2009

(51) Int. Cl. H03K 17/78

(52) U.S. Cl. 327/512

(57) ABSTRACT

A semiconductor device includes: a high VT part including a first transistor with first threshold voltage; a low VT part including a second transistor with second threshold voltage lower than the first voltage; a temperature detector which measures a temperature of the semiconductor device, determines whether the temperature is in a high temperature state where the temperature is higher than a predetermined temperature or a low temperature state where the temperature is lower than the predetermined temperature, and outputs a signal indicating the high temperature state or the low temperature state; and a controller which receives the signal indicating the high temperature state or the signal indicating the low temperature state, and performs control to cause the high VT part to operate based on the signal indicating the high temperature state and to cause the low VT part to operate based on the signal indicating the low temperature state.

### INCORPORATION BY REFERENCE

This application is based upon and claims the benefit of priority from Japanese patent application No. 2009-134869, filed on Jun. 4, 2009, the disclosure of which is incorporated herein in its entirety by reference.

### FIELD OF THE INVENTION

The present invention relates to a semiconductor device and a method of operating the same.

### BACKGROUND

A semiconductor device including a semiconductor integrated circuit has a general operating temperature range of 0° C. to 70° C., and a power source voltage is determined so as to operate the semiconductor device within this temperature range. For example, a semiconductor device including a complementary metal oxide semiconductor (CMOS) generally has a power source voltage of 1.5 V±0.15 V in the case of a 0.15-μm process and a power source voltage of 1.0 V±0.1 V or 1.2 V±0.12 V in the case of a 90-nm process. Recently, mounting of semiconductor devices on AV devices and automobiles has been becoming increasingly common, and hence semiconductor devices are used in various operation environments such as the outdoors and the inside of a vehicle. Considering this, semiconductor devices are required to have a wider guaranteed operating temperature range of −40° C. to 110° C., instead of the conventional operating temperature range of 0° C. to 70° C.

Techniques to improve the operation of a semiconductor device in a low-temperature state are disclosed in Patent Documents 1 to 3. Patent Document 1 discloses a semiconductor device capable of stably operating in a wide temperature range. FIG. 1 is a diagram showing the semiconductor integrated circuit in Patent Document 1, which includes a differential amplifier 101 of a CMOS structure. Referring to FIG. 1, the differential amplifier 101 includes PMOS transistors QP1 and QP2 constituting a current mirror load, differential NMOS transistors QN1 and QN2, and a current source NMOS transistor QN3. In the vicinity of the differential amplifier 101, a heater 102 configured of a resistor R1 and a heater 103 configured of a resistor R2 are disposed. Heat generated by flowing of currents in the resistors R1 and R2 is conducted to the differential amplifier 101. Such a semiconductor integrated circuit is capable of operating stably even in a low temperature environment of −50° C. since the heaters 102 and 103 heat the differential amplifier 101.

Patent Document 2 discloses a semiconductor integrated circuit guaranteed to operate in a low temperature environment. FIG. 2 is a block diagram of the semiconductor integrated circuit in Patent Document 2. Referring to FIG. 2, the semiconductor integrated circuit 110 includes a function circuit 111 which implements functions, a temperature detecting element 112 which detects the temperature of the function circuit 111, and a control circuit 113 which controls operations and outputs of the function circuit 111. The control circuit 113 determines whether the temperature of the function circuit 111 is lower than a minimum temperature at which the functions of the function circuit 111 are guaranteed, on the basis of a signal from the temperature detecting element 112. When the temperature is lower than the minimum temperature, the control circuit 113 performs such a control that a signal appearing in an output signal line 114 of the function circuit 111 would not be outputted from an output signal line 115 to the outside as an output of the semiconductor integrated circuit 110 until the temperature of the function circuit 111 becomes higher than the minimum temperature. Additionally, the control circuit 113 increases the temperature of the function circuit 111 by operating some or all of the circuits in the function circuit 111. When the temperature of the function circuit 111 reaches a temperature higher than the minimum temperature, the signal appearing in the output signal line 114 of the function circuit 111 is outputted to the outside by a control of the control circuit 113. Such a semiconductor integrated circuit is capable of operating the function circuit 111 properly even in a low temperature environment where the operation of the function circuit 111 is not guaranteed.

Patent document 3 discloses a temperature adaptive circuit capable of operating a circuit such as a large scale integrated circuit (LSI) in a temperature range in which the circuit operates properly, even at a time such as when a power source is turned on. The temperature adaptive circuit includes: an operation controller which outputs either an operation instruction to perform a normal operation or an operation instruction to perform a temperature increase operation; and a circuit which operates selectively on the basis of the operation instruction from the operation controller. Here, the normal operation is an operation performed in a temperature range in which the circuit can operate properly, and the temperature increase operation is an operation performed to increase the temperature. Such a temperature adaptive circuit is capable of performing the normal operation after increasing the temperature of the LSI to a predetermined temperature.

### [Patent Documents]

### [Patent Document 1] Japanese Patent Application Publication 2001-345420

### [Patent Document 2] Japanese Patent Application Publication 2004-6473

### [Patent Document 3] Japanese Patent Application Publication 2005-340486

### SUMMARY

The inventors of the present application have found the following problems in Patent Documents 1 to 3. The technique of Patent Document 1 requires provision of a dedicated heater in a semiconductor chip to assist a specific circuit block such as an analog circuit or a memory circuit to operate at a low temperature. Accordingly, the technique of Patent Document 1 has a problem that the layout in the semiconductor chip is limited, and the freedom of the layout in the semiconductor chip is restricted. The technique of Patent Document 2 prohibits a semiconductor chip from outputting data until the temperature of the semiconductor chip rises to the predetermined temperature. Accordingly, the semiconductor chip of Patent Document 2 has problem of losing the real-time property when operating at a low temperature. The technique of Patent Document 3 requires provision of a dedicated function part for controlling a temperature increase in order to increase the temperature of a semiconductor chip. Accordingly, the technique of Patent Document 3 has a problem that a circuit, which has nothing to do with original functions required for the semiconductor chip, has to be implemented in the semiconductor chip.

When a semiconductor device constituted of a CMOS with an operating temperature range of 0° C. to 70° C. operates in a range of −40° to 110° C., a leak current increases in a high temperature state (70° C. to 110° C. in this case). Considering operations in the high temperature state, the semiconductor device is desired to be constituted of a high VT transistor with a high threshold voltage and a small leak current. However, the semiconductor device constituted by using the high VT transistor does not operate in a low temperature state (−40° C. to 0° C. in this case) with application of a power source voltage for the high VT transistor, that is, a voltage of 1.5 V±0.15 V or 1.0 V±0.1 V. For this reason, the power source voltage for the semiconductor device constituted by using the high VT transistor has to be changed to one for operation in the low temperature state. For example, a semiconductor device formed of the high VT transistor in a 90-nm process needs to be guaranteed to operate with a supply voltage of 1.2 V±0.12 V, even though the semiconductor device generally operates with a supply voltage to 1.0 V±0.1 V.

When the operation voltage of the semiconductor device is determined in consideration of the operation in the low temperature state, the semiconductor device needs to be applied with a power source voltage sufficiently high for the operation in the low temperature state. However, a leak current flowing in the semiconductor device increases when the semiconductor device operates in the high temperature state with application of a high power source voltage. Increase in the leak current leads to increase in the power consumption of the semiconductor device. It is essential for a recent semiconductor device to reduce the leak power in a standby state to enhance the energy efficiency of equipment to which the semiconductor device is mounted. Thus, increase in the leak power in the high temperature state is not preferable, since it becomes more difficult to meet such needs. In other words, there is a demand for a semiconductor device which operates in a wide temperature range and has a small leak current.

Hereinafter, a solution to the problems will be described by showing, in parentheses, the reference numerals used in Description of Embodiment. These reference numerals are added to clarify correspondences between the descriptions in Claims and the descriptions in Description of Embodiment, and should not be used to determine the technical scope of the invention described in Claims.

A semiconductor device (1) of the present invention includes: a high VT part (7) including a first transistor with a threshold voltage of a first voltage; a low VT part (8) including a second transistor with a threshold voltage of a second voltage lower than the first voltage; a temperature detector (6) which measures a temperature of the semiconductor device, determines whether the temperature is in a high temperature state where the temperature is higher than a predetermined temperature or a low temperature state where the temperature is lower than the predetermined temperature, and outputs a signal indicating the high temperature state or a signal indicating the low temperature state; and a controller (9) which receives either the signal indicating the high temperature state or the signal indicating the low temperature state, and performs control to cause the high VT part (7) to operate based on the signal indicating the high temperature state and to cause the low VT part (8) to operate based on the signal indicating the low temperature state. The semiconductor device (1) having the above-described configuration can operate the high VT part (7) including the first transistor with the high threshold voltage in the high temperature state, and the low VT part (8) including the second transistor with the low threshold voltage in the low temperature state.

The semiconductor device of the present invention can operate while suppressing a leak current in a wide temperature range without changing a power source voltage.

### BRIEF DESCRIPTION OF THE DRAWINGS

FIG. 1 is a diagram showing a semiconductor integrated circuit of Patent Document 1, which includes a differential amplifier 101 of a CMOS structure.

FIG. 2 is a block diagram of a semiconductor integrated circuit of Patent Document 2.

FIG. 3 is a block diagram showing a configuration example of a semiconductor device 1 of the present invention.

FIG. 4 is a flowchart showing an operation of the semiconductor device 1 of the present invention.

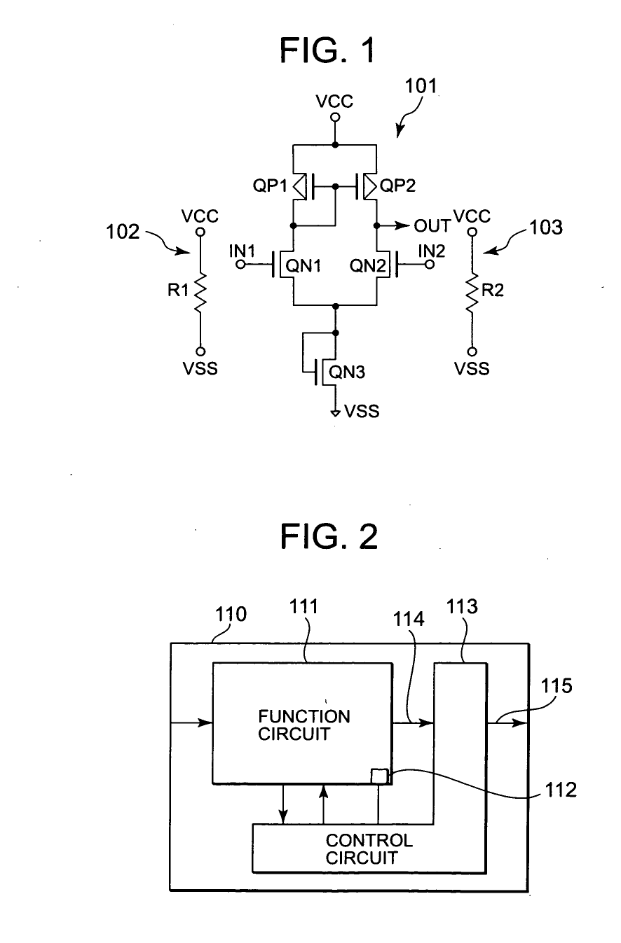

### DETAILED DESCRIPTION OF THE EXEMPLARY EMBODIMENTS

Hereinafter, a semiconductor device according to an embodiment of the present invention and a method of operating the semiconductor device will be described with reference to the accompanying drawings.

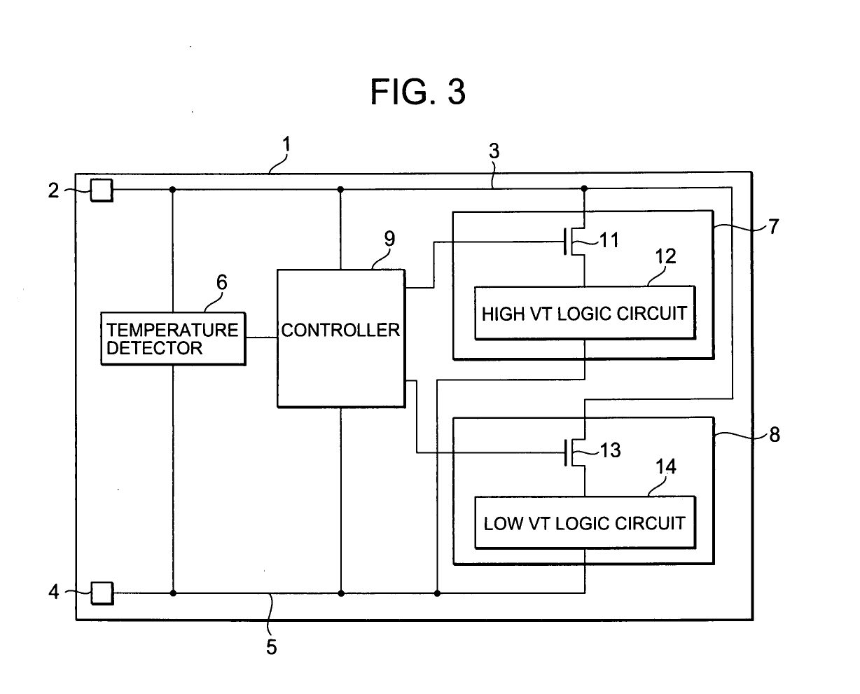

FIG. 3 is a block diagram showing a configuration example of a semiconductor device 1 of the present invention. As shown in FIG. 3, the semiconductor device 1 includes a power source terminal 2, an internal power source wiring 3, a GND terminal 4, an internal GND wiring 5, a temperature detector 6, a high VT part 7, a low VT part 8, and a controller 9.

The power source terminal 2 is a terminal to which power from an external power source of the semiconductor device 1 is supplied. The internal power source wiring 3 is a wiring which supplies power to each part in the semiconductor device 1. The GND terminal 4 is a ground terminal of the semiconductor device 1. The internal GND wiring 5 is a wiring which is connected to each part of the semiconductor device 1, and is connected to the GND terminal 4.

The temperature detector 6 measures the temperature of the semiconductor device 1, and determines whether the temperature of the semiconductor device 1 is in a high temperature state or a low temperature state on the basis of a threshold of the temperature. An example of a method employed by the temperature detector 6 is a method of measuring the temperature by using a temperature sensor such as a thermister. An example of the threshold at which the temperature detector 6 distinguishes the high temperature state from the low temperature state is 0° C. Here, the temperature detector 6 can detect a state at 0° C. or higher and 110° C. or lower as the high temperature state and a state at less than 0° C. and −40° C. or higher as the low temperature state in a temperature range from −40° C. to 110° C. The temperature detector 6 outputs a signal indicating the high temperature state or the low temperature state to the controller 9 on the basis of the determined temperature of the semiconductor device 1.

The high VT part 7 operates on the basis of a signal received from the controller 9. In particular, the high VT part 7 operates when the temperature of the semiconductor device 1 is in the high temperature state (for example, 0° C. or higher and 110° C. or lower). The high VT part 7 includes a high VT logic circuit power source switch 11 and a high VT logic circuit 12.

The high VT logic circuit power source switch 11 receives the signal from the controller 9, and switches between ON and OFF of power supply to the high VT logic circuit 12. The high VT logic circuit 12 is a circuit which includes a transistor with a high threshold voltage VT and a small leak current. While the power supply is switched to ON by the high VT logic circuit power source switch 11, the high VT logic circuit 12 is supplied with power and thereby operates.

As similar to the high VT part 7, the low VT part 8 operates on the basis of a signal received from the controller 9. In particular, the low VT part 8 operates when the temperature of the semiconductor device 1 is in the low temperature state (for example, −40° C. or higher and less than 0° C.). The low VT part 8 includes a low VT logic circuit power source switch 13 and a low VT logic circuit 14.

The low VT logic circuit power source switch 13 receives the signal from controller 9, and switches between ON and OFF of power supply to the low VT logic circuit 14. The low VT logic circuit 14 is a circuit which includes a transistor with a lower threshold voltage VT than the high VT logic circuit 12 and a large leak current. While power supply is switched to ON by the low VT logic circuit power source switch 13, the low VT logic circuit 14 is supplied with power and thereby operates.

The controller 9 performs control to cause either one of the high VT logic circuit 12 and the low VT logic circuit 14 to operate on the basis of the temperature of the semiconductor device 1. The controller 9 receives a signal indicating whether the semiconductor device 1 is in the high temperature state or the low temperature state, from the temperature detector 6. When receiving a signal indicating the high temperature state, the controller 9 outputs a signal to cause the high VT part 7 to operate. Specifically, the controller 9 outputs, to the high VT logic circuit power source switch 11, a signal to switch the power supply to ON so that the high VT logic circuit 12 would operate. When receiving the signal to switch the power supply to ON, the high VT logic circuit power source switch 11 supplies power to the high VT logic circuit 12. Thereby, the high VT logic circuit 12 is supplied with power and operates. At this time, the controller 9 outputs, to the low VT logic circuit power source switch 13, a signal to switch power supply to OFF so that the low VT logic circuit 14 of the low VT part 8 would not operate. On the other hand, when receiving a signal indicating the low temperature state, the controller 9 outputs a signal to cause the low VT part 8 to operate. Specifically, the controller 9 outputs, to the low VT logic circuit power source switch 13, a signal to switch the power supply to ON so that the low VT logic circuit 14 would operate. When receiving the signal to switch the power supply to ON, the low VT logic circuit power source switch 13 supplies power to the low VT logic circuit 14. Thereby, the low VT logic circuit 14 is supplied with power and operates. At this time, the controller 9 outputs, to the high VT logic circuit power source switch 11, a signal to switch the power supply to OFF so that the high VT logic circuit 12 of the high VT part 7 would not operate.

As described above, when the temperature detector 6 detects the low temperature state, the semiconductor device 1 causes the low VT logic circuit 14 to operate. When the low VT logic circuit 14 operates and power is consumed, the temperature of the semiconductor device 1 rises. If the low VT logic circuit 14 is continuously operated after the temperature has reached the high temperature state, the leak current increases. To counter this, when the temperature detector 6 determines that the temperature of the semiconductor device 1 is in the high temperature state, the controller 9 outputs, to the low VT logic circuit power source switch 13, a signal to switch the power supply to OFF, and stops the operation of the low VT logic circuit 14. Additionally, the controller 9 outputs, to the high VT logic circuit power source switch 11, a signal to switch power supply to ON, and causes the high VT logic circuit 12 to operate. In this way, the semiconductor device 1 performs such switching between the high VT logic circuit 12 and the low VT logic circuit 14 according to the temperature. Accordingly, the semiconductor device 1 can operate while suppressing a leak current in a wide temperature range without changing a power source voltage.

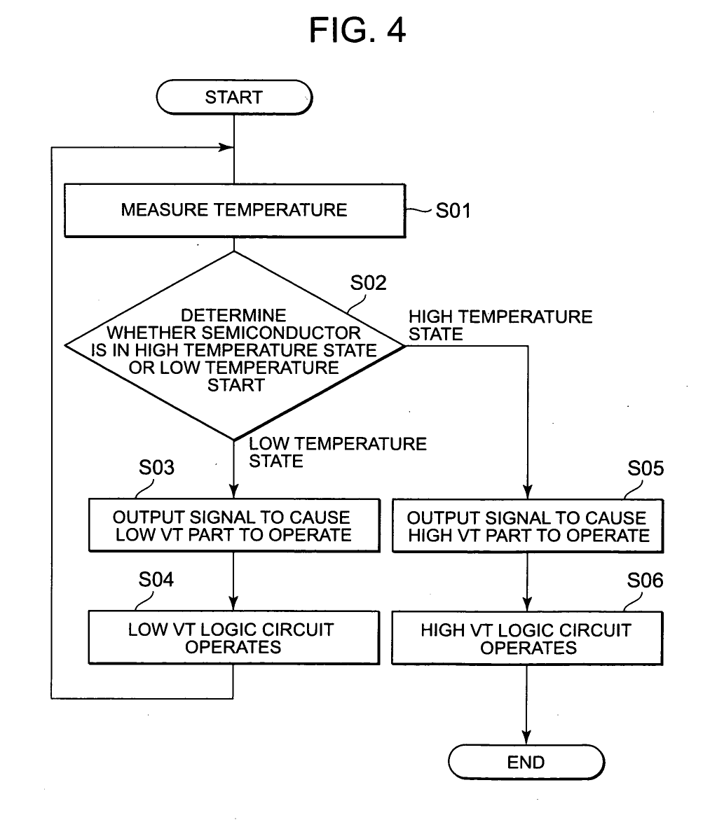

FIG. 4 is a flowchart showing an operation of the semiconductor device 1 of the present invention. The method of operating the semiconductor device of the present invention will be described with reference to FIG. 4.

The temperature detector 6 measures the temperature of the semiconductor device 1 (Step S01).

The temperature detector 6 determines whether the temperature of the semiconductor device 1 is in the low temperature state or the high temperature state on the basis of the threshold of the temperature (Step S02).

In Step S02, when determining that the temperature of the semiconductor device 1 is in the low temperature state, the temperature detector 6 outputs a signal indicating the low temperature state to the controller 9. The controller 9 receives the signal indicating the low temperature state and outputs a signal to cause the low VT part 8 to operate. Specifically, the controller 9 outputs, to the low VT logic circuit power source switch 13, a signal to switch power supply to ON so that the low VT logic circuit 14 would operate (Step S03).

When receiving the signal to switch power supply to ON, the low VT logic circuit power source switch 13 supplies power to the low VT logic circuit 14. Thereby, the low VT logic circuit 14 is supplied with power and operates (Step S04). At this time, the controller 9 outputs, to the high VT logic circuit power source switch 11, a signal to switch the power supply to OFF so that the high VT logic circuit 12 of the high VT part 7 would not operate. When the low VT logic circuit 14 operates, the temperature of the semiconductor device 1 rises, and the operation method returns to Step S01 in which the temperature detector 6 measures the temperature.

In Step 02, when determining that the temperature of the semiconductor device 1 is in the high temperature state, the temperature detector 6 outputs a signal indicating the high temperature state to the controller 9. The controller 9 receives the signal indicating the high temperature state and outputs a signal to cause the high VT part 7 to operate. Specifically, the controller 9 outputs, to the high VT logic circuit power source switch 11, a signal to switch power supply to ON so that the high VT logic circuit 12 would operate (Step S05).

When receiving the signal to switch power supply to ON, the high VT logic circuit power source switch 11 supplies power to the high VT logic circuit 12. Thereby, the high VT logic circuit 12 is supplied with power and operates (Step S06). At this time, the controller 9 outputs, to the low VT logic circuit power source switch 13, a signal to switch the power supply to OFF so that the low VT logic circuit 14 of the low VT part 8 would not operate. After the high VT logic circuit 12 started to operate, the operation method may return to Step S01 to measure the temperature of the semiconductor device 1.

The semiconductor device 1 of the present invention is capable of performing switching so that the high VT logic circuit 12 with a high threshold voltage would operate in the high temperature state and the low VT logic circuit 14 with a low threshold voltage would operate in the low temperature state. Accordingly, the semiconductor device 1 can suppress a leak current (power consumption) in the high temperature state, and can at the same time operate in a wide temperature range without changing the power source voltage. The circuit scale of a semiconductor integrated circuit in a recent semiconductor device is increasing due to development of finer designs incorporating 90-nm, 55-nm, and 40-nm processes, which are achieved by improvement in processing technology. However, the number of I/Os to implement the functions of a semiconductor device is the same or larger than that of the conventional semiconductor device. In other words, a prime factor determining the chip size of a semiconductor device tends to depend more on an I/O region (the number of I/Os) than the internal circuit scale. In other words, the semiconductor device 1 of the present invention makes effective use of the internal region since an excessive space left unused in the internal region is used by the dual internal circuit. Thus, the semiconductor device 1 has an effect of being capable of operating in a wide temperature range.

What is claimed is:

1. A semiconductor device comprising:
a high VT part including a first transistor with a threshold voltage of a first voltage;
a low VT part including a second transistor with a threshold voltage of a second voltage lower than the first voltage;
a temperature detector which measures a temperature of the semiconductor device, determines whether the temperature is in a high temperature state where the temperature is higher than a predetermined temperature or a low temperature state where the temperature is lower than the predetermined temperature, and outputs a signal indicating the high temperature state or a signal indicating the low temperature state; and
a controller which receives either the signal indicating the high temperature state or the signal indicating the low temperature state, and performs control to cause the high VT part to operate based on the signal indicating the high temperature state and to cause the low VT part to operate based on the signal indicating the low temperature state.

2. The semiconductor device according to claim 1, wherein
the high VT part includes:
a high VT logic circuit including the first transistor; and
a first switch part which switches between ON and OFF of power supply to the high VT logic circuit,
the low VT part includes:
a low VT logic circuit including the second transistor; and
a second switch part which switches between ON and OFF of power supply to the low VT logic circuit,
the controller outputs a first signal to the first switch part on the basis of the signal indicating the high temperature state, and outputs a second signal to the second switch part on the basis of the signal indicating the low temperature state,
the first switch part supplies power to the high VT logic circuit on the basis of the first signal, and
the second switch part supplies power to the low VT logic circuit on the basis of the second signal.

3. A method of operating a semiconductor device comprising the steps of:
measuring a temperature of the semiconductor device;
determining whether the temperature is in a high temperature state where the temperature is higher than a predetermined temperature or a low temperature state where the temperature is lower than the predetermined temperature;
outputting a signal indicating the high temperature state or a signal indicating the low temperature state on the basis of the determination;
receiving the signal indicating the high temperature state or the signal indicating the low temperature state; and
operating a high VT part including a first transistor with a threshold voltage of a first voltage on the basis of the signal indicating the high temperature state, and operating a low VT part including a second transistor with a threshold voltage of a second voltage lower than the first voltage on the basis of the signal indicating the low temperature state.

4. The method of operating a semiconductor device according to claim 3, wherein the step of operating the high VT part and the low VT part includes the steps of:
outputting a first signal on the basis of the signal indicating the high temperature state; and
supplying power to the high VT logic circuit including the first transistor, on the basis of the first signal.

5. The method of operating a semiconductor device according to claim 3, wherein the step of operating the high VT part and the low VT part includes the steps of:
outputting a second signal on the basis of the signal indicating the low temperature state; and
supplying power to the low VT logic circuit including the second transistor, on the basis of the second signal.

6. The method of operating a semiconductor device according to claim 4, wherein the step of operating the high VT part and the low VT part includes the steps of:
outputting a second signal on the basis of the signal indicating the low temperature state; and
supplying power to the low VT logic circuit including the second transistor, on the basis of the second signal.
